(19) United States
(12) Patent Application Publication
(10) Pub. No.: US 2010/0289119 A1
(43) Pub. Date: Nov. 18, 2010

(54) INTEGRATED CAPACITOR

(76) Inventors: Tao Cheng, Hsinchu City (TW); Wen-Lin Chen, Chia-Yi Hsien (TW)

Correspondence Address: NORTH AMERICA INTELLECTUAL PROPERTY CORPORATION, P.O. BOX 506, MERRIFIELD, VA, 22116, US

(21) Appl. No.: 12/845,778

(22) Filed: Jul. 29, 2010

Related U.S. Application Data
(62) Division of application No. 12/197,324, filed on Aug. 25, 2008.

(51) Int. Cl. H01L 27/02

(52) U.S. Cl. 257/532; 257/E27.009

(57) ABSTRACT

According to the preferred embodiment, an integrated capacitor having a key-shaped structure is provided. The integrated capacitor comprises a first pair of key-shaped metal patterns and a second pair of key-shaped metal patterns. The first pair of key-shaped metal patterns engages with the second pair of key-shaped metal patterns, and a dielectric layer is situated therebetween.

### CROSS REFERENCE TO RELATED APPLICATIONS

This application is a division of U.S. application Ser. No. 12/197,324 filed Aug. 25, 2008, which is incorporated herein by reference.

### BACKGROUND OF THE INVENTION

1. Field of the Invention

The invention relates generally to the field of integrated circuits. More particularly, the invention relates to an integrated capacitor in an integrated circuit with improved intra-layer capacitance.

2. Description of the Prior Art

Capacitors are critical components in the integrated circuit devices of today. As devices become smaller and circuit density increases, it is desirable that capacitors maintain their level of capacitance while taking up a smaller floor area on the circuit.

The value of capacitance, C, for a parallel plate capacitor is approximated by the formula:

C =k(A/d)

where A is the area of the metal plates calculated by multiplying the length and width of the metal plates, d is the separation between the metal plates, and k is a constant which includes therein the dielectric constant of the region between the metal plates.

U. S. Pat. No. 5,939,766 discloses a capacitor based on intra-layer capacitive coupling between metal lines on a single metal layer, rather than interlayer capacitive coupling between two separate metal layers. The capacitor comprises a first layer of metal patterned into a plurality of first lines each having two ends and a length there-between; a first connecting electrode coupled to one end of each of the first lines, each of the first lines electrically isolated except for the connection formed with the first connecting electrode; a plurality of second lines each having two ends and a length there-between arranged such the plurality of first lines and the plurality of second lines are interdigitated; and a second connecting electrode coupled to one end of each of the second lines, each of the second lines electrically isolated except for the connection formed with the second connecting electrode.

### SUMMARY OF THE INVENTION

It is one object of this invention to provide an improved integrated capacitor in an integrated circuit with improved intra-layer capacitance.

According to the claimed invention, an integrated capacitor having a key-shaped structure is provided. The integrated capacitor comprises a first pair of key-shaped metal patterns and a second pair of key-shaped metal patterns. The first pair of key-shaped metal patterns engages with the second pair of key-shaped metal patterns, and a dielectric layer is situated therebetween.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 is a fragmentary top view of an integrated capacitor in accordance with the first preferred embodiment of this invention;

FIG. 2 is a top view of an integrated capacitor in accordance with the second preferred embodiment of this invention; and

FIG. 3 is a top view of an integrated capacitor in accordance with the third preferred embodiment of this invention.

### DETAILED DESCRIPTION

The invention pertains to an integrated capacitor with improved intra-layer capacitance that is suited for analog/digital (A/D) converters, digital/analog (D/A) converters, switch cap circuits or other applications. The integrated capacitor of this invention is fully compatible with the logic processes.

In order to accommodate higher packing densities, the spacing between metal lines of the same metal layer in a modern integrated circuit chip is becoming smaller and smaller. Conventionally, the metal pitch or the minimum spacing between metal lines is smaller than the thickness of the interlayer dielectric. Each metal line in a layer of metal is capacitively coupled to the adjacent metal lines in that same layer of metal. Capacitive coupling between different metal lines formed from the same layer of metal is referred to as intra-layer capacitance.

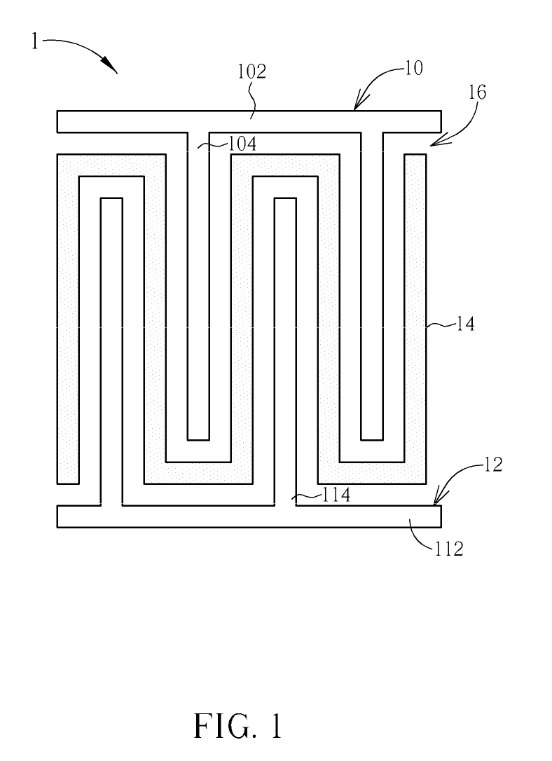

FIG. 1 is a fragmentary top view of an integrated capacitor in accordance with the first preferred embodiment of this invention. As shown in FIG. 1, the integrated capacitor 1 has a unique comb-meander structure comprising two comb-shaped metal patterns 10 and 12 interdigitating with one another, and a meandering metal pattern 14 traversing the spacing between the two comb-shaped metal patterns 10 and 12. A dielectric layer 16 is situated between the comb-shaped metal patterns 10 and 12 and the meandering metal pattern 14.

The comb-shaped metal pattern 10 comprises a connecting electrode 102 and a plurality of finger electrodes 104 that are perpendicular to the connecting electrode 102. Likewise, the comb-shaped metal pattern 12 comprises a connecting electrode 112 and a plurality of finger electrodes 114 that are perpendicular to the connecting electrode 112.

The two comb-shaped metal patterns 10 and 12 may be electrically coupled to the same polarity or coupled to the same voltage level. The meandering metal pattern 14 may be electrically coupled to a polarity that is opposite to that of the two comb-shaped metal patterns 10 and 12. The two comb-shaped metal patterns 10 and 12 and the meandering metal pattern 14 may be composed of copper, aluminum or alloys thereof.

According to the first preferred embodiment of this invention, the two comb-shaped metal patterns 10 and 12 and the meandering metal pattern 14 are metal lines of the same layer of metal interconnection. However, it is understood that the two comb-shaped metal patterns 10 and 12 and the meandering metal pattern 14 may be metal plates formed from stacked metal lines and vias.

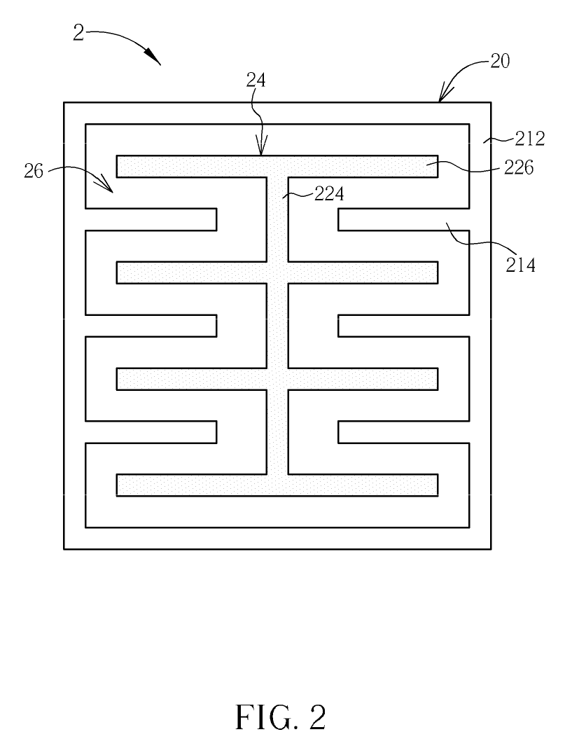

FIG. 2 is a top view of an integrated capacitor in accordance with the second preferred embodiment of this invention. As shown in FIG. 2, the integrated capacitor 2 has a fence-rail structure comprising a fence-shaped, outer metal pattern 20 encompassing an inner metal pattern 24. A dielectric layer 26 is situated between the outer metal pattern 20 and the inner metal pattern 24.

The outer metal pattern 20 comprises a rectangular metal frame 212 and a plurality of finger electrodes 214 protruding inside the rectangular metal frame 212. Each of the finger electrodes 214 may be perpendicular to a corresponding side of the metal frame 212.

The inner metal pattern 24 has a rail-shaped structure comprising one single vertical metal line 224 and a plurality of horizontal metal lines 226, wherein the vertical metal line 224 interconnects the plurality of horizontal metal lines 226. The plurality of horizontal metal lines 226 interdigitate with the finger electrodes 214 of the outer metal pattern 20.

The outer metal pattern 20 and the inner metal pattern 24 may be coupled to opposite polarities. The outer metal pattern 20 and the inner metal pattern 24 may be composed of copper, aluminum or alloys thereof.

According to the second preferred embodiment of this invention, the outer metal pattern 20 and the inner metal pattern 24 are metal lines of the same layer of metal interconnection. In another case, the outer metal pattern 20 and the inner metal pattern 24 may be metal plates formed from stacked metal lines and vias.

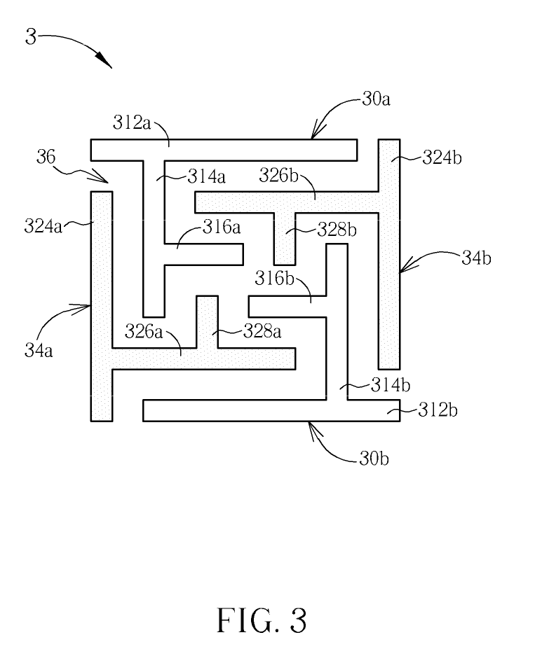

FIG. 3 is a top view of an integrated capacitor in accordance with the third preferred embodiment of this invention. As shown in FIG. 3, the integrated capacitor 3 comprises a first pair of key-shaped metal patterns 30a and 30b and a second pair of key-shaped metal patterns 34a and 34b. The first pair of key-shaped metal patterns 30a and 30b engages with the second pair of key-shaped metal patterns 34a and 34b. A dielectric layer 36 is situated therebetween.

According to this embodiment, the key-shaped metal patterns 30a and 30b may be coupled to the same polarity, while the key-shaped metal patterns 34a and 34b may be coupled to a polarity that is opposite to that of the key-shaped metal patterns 30a and 30b.

The key-shaped metal pattern 30a has a longer horizontal line segment 312a, a shorter horizontal line segment 316a and a vertical line segment 314a for connecting the longer horizontal line segment 312a with the shorter horizontal line segment 316a. Likewise, the key-shaped metal pattern 30b has a longer horizontal line segment 312b, a shorter horizontal line segment 316b and a vertical line segment 314b for connecting the longer horizontal line segment 312b with the shorter horizontal line segment 316b.

The key-shaped metal pattern 34a has a longer vertical line segment 324a, a shorter vertical line segment 328a and a horizontal line segment 326a for connecting the vertical line segment 324a with the vertical line segment 328a. The key-shaped metal pattern 34b has a longer vertical line segment 324b, a shorter vertical line segment 328b and a horizontal line segment 326b for connecting the vertical line segment 324b with the vertical line segment 328b.

According to this invention, the key-shaped metal patterns 30a, 30b, 34a and 34b are metal lines of the same layer of metal interconnection. In another case, the key-shaped metal patterns 30a, 30b, 34a and 34b may be metal plates formed from stacked metal lines and vias.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An integrated capacitor comprising a first pair of key-shaped metal patterns and a second pair of key-shaped metal patterns, wherein the first pair of key-shaped metal patterns engages with the second pair of key-shaped metal patterns, and wherein a dielectric layer is situated therebetween.

2. The integrated capacitor of claim 1 wherein the first pair of key-shaped metal patterns is coupled to a first polarity, while the second pair of key-shaped metal patterns is coupled to a second polarity that is opposite to the first polarity.
